(19) United States
(12) Patent Application Publication
(10) Pub. No.: US 2026/0190673 A1
(43) Pub. Date: Jul. 2, 2026

(54) DISPLAY APPARATUS AND METHOD OF MANUFACTURING THE SAME

(71) Applicant: LG Display Co., Ltd., Seoul (KR)

(72) Inventors: Chung Hyeon LEE, Paju-si (KR); Se Yong LEE, Paju-si (KR)

(73) Assignee: LG Display Co., Ltd., Seoul (KR)

(21) Appl. No.: 19/435,456

(22) Filed: Dec. 29, 2025

(30) Foreign Application Priority Data
Dec. 31, 2024 (KR) 10-2024-0203038

(51) Int. Cl. H10K 59/124; H10K 59/122

(52) U.S. Cl. CPC H10K 59/124; H10K 59/122

(57) ABSTRACT

A display apparatus includes a display panel including subpixels and a driver configured to drive the display panel. Each subpixel includes a first light emitting device disposed on a substrate and disposed on a planarization layer. The planarization layer includes a recessed region where a portion of its surface is removed to form a recess. The structure of the recessed region, including depth or side slope, varies according to a region defined on the substrate. This region dependent recessed structure is designed to improve light extraction efficiency, enhance front and side viewing angles, and reduce power consumption by increasing the emission area and directing light more effectively. The recessed region may be selectively applied to specific subpixels, such as those containing a blue light emitting device, to extend operational lifetime and improve luminance characteristics. This arrangement provides uniform display performance across flat, curved, and bent portions of the display panel.

### CROSS-REFERENCE TO RELATED APPLICATIONS

This application claims the benefit of the Korean Patent Application No. 10-2024-0203038 filed on December 31, 2024, which is hereby incorporated by reference as if fully set forth herein.

### BACKGROUND

### Technical Field

The present disclosure relates to a display apparatus and a method of manufacturing the same.

### Description of the Related Art

As information technology advances, the market for display apparatuses which are connection mediums connecting a user with information is growing. Therefore, the use of display apparatuses such as light emitting display apparatuses, quantum dot display (QDD) apparatuses, and liquid crystal display (LCD) apparatuses is increasing.

The display apparatuses described above include a display panel which includes a plurality of subpixels, a driver which outputs a driving signal for driving the display panel, and a power supply which generates power which is to be supplied to the display panel or the driver.

In such display apparatuses, when the driving signal (for example, a scan signal and a data signal) is supplied to each of the subpixels provided in the display panel, a selected subpixel may transmit light or may self-emit light, and thus, an image may be displayed.

### BRIEF SUMMARY

The subject matter relates to a display apparatus that includes a planarization layer with recessed regions formed beneath subpixels. The depth and side slope of these recessed regions are varied according to specific areas of the display panel. This structural variation is configured to improve light extraction efficiency, enhance front and side viewing angles, increase luminance uniformity, and extend operational lifetime while reducing overall power consumption. The structure enables both front and lateral emission and reflection of light, which contributes to minimizing color shift and brightness loss, particularly in peripheral or curved portions of the display.

A particular configuration applies the recessed planarization structure selectively to blue subpixels, which are known to degrade faster and require higher drive currents. By modifying the geometry beneath these subpixels, the structure allows for lower drive current operation and longer lifespan. Additionally, the blue subpixels can be resized to more closely match the red and green subpixels, which enhances resolution and design flexibility. These recesses are formed using photolithographic techniques such as halftone or multitone masking, enabling spatial control of depth and taper in a single exposure step.

This structural approach is well suited for application in flexible and curved organic light emitting diode panels, where mechanical deformation or panel shape may otherwise result in localized brightness reduction. By adjusting the recess profiles in relation to the display geometry, the panel achieves a consistent light output and viewing experience across different regions. This allows for improved performance without relying on electronic compensation algorithms or additional optical elements.

To further elaborate, the present disclosure may secure a wide emission region in the same opening area and may enhance a front viewing angle and a side viewing angle, based on front light emission and side light emission, thereby improving light extraction efficiency and a viewing angle characteristic. Also, the present disclosure may enhance (long lifetime) a lifetime, based on securing a wide emission region, and may enhance a luminance characteristic and a viewing angle characteristic (increase front/viewing angle luminance), thereby decreasing power consumption and minimizing a color shift.

To achieve these technical benefits and other advantages and in accordance with the purpose of the disclosure, as embodied and broadly described herein, a display apparatus includes: a display panel including subpixels; and a driver configured to drive the display panel, wherein each of the subpixels includes a first light emitting device disposed on a substrate and disposed on a planarization layer including a recessed region where a surface thereof is removed to be recessed, and the recessed region has a structure changed based on a region defined on the substrate.

A depth of the recessed region may be changed based on the region defined on the substrate.

A side slope of the recessed region may be changed based on the region defined on the substrate.

The recessed region may be included in subpixels disposed in a second region and a third region with respect to a first region of the substrate.

The subpixels disposed in the first region may not include the recessed region.

The recessed region may be deepened by block units or progressively toward a second direction of the substrate from a first direction of the substrate.

The subpixels may include a red subpixel, a green subpixel, and a blue subpixel, and the first light emitting device may be included in at least one of the red subpixel, the green subpixel, and the blue subpixel.

The first light emitting device may be included in the blue subpixel.

In another aspect of the present disclosure, a display apparatus includes: a substrate; a planarization layer disposed on the substrate and including a recessed region which is controlled so that a surface thereof is recessed; and a light emitting device disposed on the planarization layer, wherein the recessed region has a shape changed based on a region defined on the substrate.

A depth of the recessed region may be changed based on the region defined on the substrate.

A side slope of the recessed region may be changed based on the region defined on the substrate.

The recessed region may be included in pixels disposed in a second region and a third region with respect to a first region of the substrate.

The pixels disposed in the first region may not include the recessed region.

The recessed region may be deepened by block units or progressively toward a second direction of the substrate from a first direction of the substrate.

The recessed region may be included in a pixel including a blue light emitting device emitting blue light.

In another aspect of the present disclosure, a method of manufacturing a display apparatus includes: a step of forming a planarization layer on a substrate; a step of forming a recessed region by removing a surface of the planarization layer to be recessed; and a step of forming a first light emitting device on the planarization layer including the recessed region, wherein the recessed region is patterned to have a structure changed based on a region defined on the substrate.

A depth of the recessed region may be changed based on the region defined on the substrate.

The present disclosure may improve light extraction efficiency and a viewing angle characteristic, based on a light emitting device including a recessed region and a non-recessed region or a light emitting device including a recessed region. Also, the present disclosure may secure a wide emission region in the same opening area and may enhance a front viewing angle and a side viewing angle, based on front light emission and side light emission. Also, the present disclosure may enhance (long lifetime) a lifetime, based on securing a wide emission region, and may enhance a luminance characteristic and a viewing angle characteristic (increase front/viewing angle luminance), thereby decreasing power consumption and minimizing a color shift.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a block diagram schematically illustrating a display apparatus according to an embodiment of the present disclosure;

FIG. 2 is an exemplary diagram illustrating a stack structure of a display panel;

FIG. 3 is a cross-sectional view illustrating a light emitting device and a peripheral layer thereof according to a first embodiment, FIG. 4 is a diagram for describing a light extraction characteristic of a light emitting device according to a first embodiment, and FIG. 5 is a diagram for describing a method of manufacturing a light emitting device according to a first embodiment;

FIG. 6 is a plan view of a display panel according to a second embodiment, and FIG. 7 is a cross-sectional view of a light emitting device disposed in first to third regions of FIG. 6;

FIG. 8 is a side view of a display panel according to a third embodiment, FIG. 9 is a cross-sectional view of a light emitting device disposed in first to third regions of FIG. 8, FIG. 10 is a diagram for describing a light extraction characteristic of a light emitting device illustrated in FIG. 9, and FIG. 11 is a diagram illustrating a luminance compensation result of a display panel according to a third embodiment;

FIG. 12 is a side view of a display panel according to a fourth embodiment, and FIG. 13 is a diagram illustrating a luminance compensation result of a display panel according to a fourth embodiment; and

FIG. 14 is a diagram illustrating one of a cross-sectional view and a plan view of a pixel disposed in a first region of a display panel according to a fifth embodiment, and FIG. 15 is a diagram illustrating one of a cross-sectional view and a plan view of a pixel disposed in a second region or a third region of a display panel according to a fifth embodiment.

### DETAILED DESCRIPTION

Hereinafter, the present disclosure will be described more fully with reference to the accompanying drawings, in which exemplary embodiments of the disclosure are shown. The disclosure may, however, be embodied in many different forms and should not be construed as being limited to the embodiments set forth herein; rather, these embodiments are provided so that this disclosure will be thorough and complete, and will fully convey the concept of the disclosure to those skilled in the art.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

As used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The term "coupled" and "in contact" should be interpreted in the same manner.

A display apparatus according to the present disclosure may be implemented as a light emitting display apparatus or a quantum dot display (QDD) apparatus. Hereinafter, for convenience of description, a light emitting display apparatus self-emitting light based on an inorganic light emitting diode or an organic light emitting diode will be described for example.

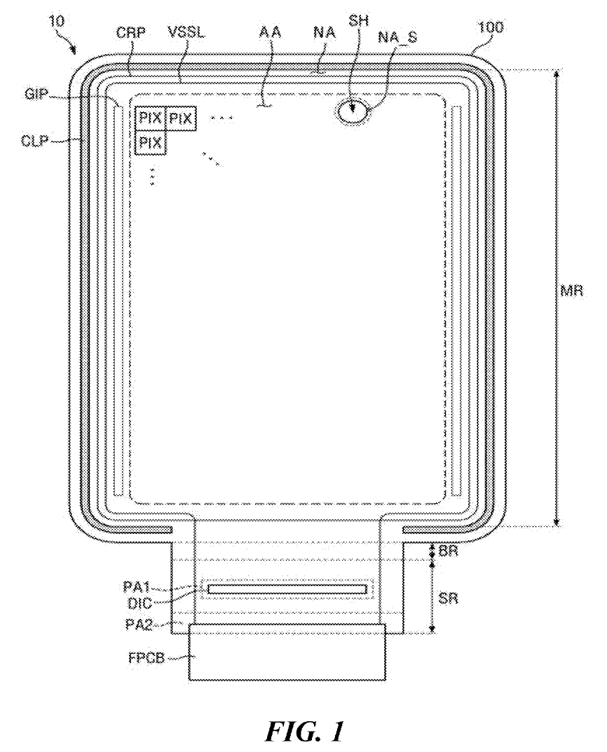

FIG. 1 is a block diagram schematically illustrating a display apparatus 10 according to an embodiment of the present disclosure.

As illustrated in FIG. 1, the display apparatus 10 may include a display panel 100 which includes a plurality of pixels PIX, a gate driver GIP which supplies a gate signal to the plurality of pixels PIX, and a data driver DIC which supplies data signals (or data voltages) to the plurality of pixels PIX. The gate driver GIP, the data driver DIC, and a power supply (not shown) may be defined as a display panel driving circuit for driving the display panel 100. At least one of devices included in the display panel driving circuit may be integrated into one integrated circuit (IC). The display panel 100 may include a display area AA where the plurality of pixels PIX are provided and a non-display area NA which is disposed to surround the display area AA and where the gate driver GIP is disposed. The display area AA may further include a groove SH where an optical device is disposed and a second non-display area NA_S at a periphery thereof. The pixel PIX may be supplied with a gate signal from the gate driver GIP through a gate line, may be supplied with a data signal from the data driver DIP through a data line, and may be supplied with a high-level voltage and a low-level voltage from the power supply (not shown). The display panel 100 may be divided into a main region MR, a sub region SR, and a bending region BR between the main region MR and the sub region SR. The main region MR may include the display area AA, the non-display area NA, the gate driver GIP, a low-level voltage line VSSL, a dam CRP, and a crack prevention line CLP. The sub region SR may include the data driver DIC, a first pad region PA1 with the data driver DIC mounted therein, and a second pad region PA2 to which an external circuit board FPCB is attached. The bending region BR may provide a structure where the sub region SR and the circuit board FPCB may be bent toward a rear surface of the display panel 100.

The display panel 100 may be implemented as a non-transmissive display panel or a transmissive display panel. The transmissive display panel may be applied to a transparent display apparatus which displays an image on a screen thereof and enables a real thing of a background to be seen. The display panel 100 may be implemented as a flexible display panel. The flexible display panel may use a plastic substrate. Each of the plurality of pixels PIX may be divided into a red subpixel, a green subpixel, and a blue subpixel for color implementation. Each of the plurality of pixels PIX may further include a white subpixel.

Touch sensors may be disposed in the display panel 100. A touch input may be sensed by using separate touch sensors, or may be sensed through the plurality of pixels PIX. The touch sensors may be arranged as an on-cell type or an add-on type in a screen of the display panel 100, or may be implemented as in-cell type touch sensors embedded in the display panel 100.

The data driver DIC may further include a controller. The controller may process video data input from the outside so as to be suitable for a size and a resolution of the display panel 100. The controller may control an operation timing of each of the gate driver GIP and the data driver DIC.

The controller may be configured to be coupled to various processors (for example, a microprocessor, a mobile processor, and an application processor), based on a device mounted thereon. A host system disposed in a front end with respect to the controller may be one of a television (TV) system, a set-top box, a navigation system, a personal computer (PC), a home theater system, a mobile device, a wearable device, and an automotive system.

The gate driver GIP may be disposed at one side or both sides of the display panel 100 in a gate in panel (GIP) type. Also, the gate driver GIP may be distributed and disposed in the display area AA of the display panel 100.

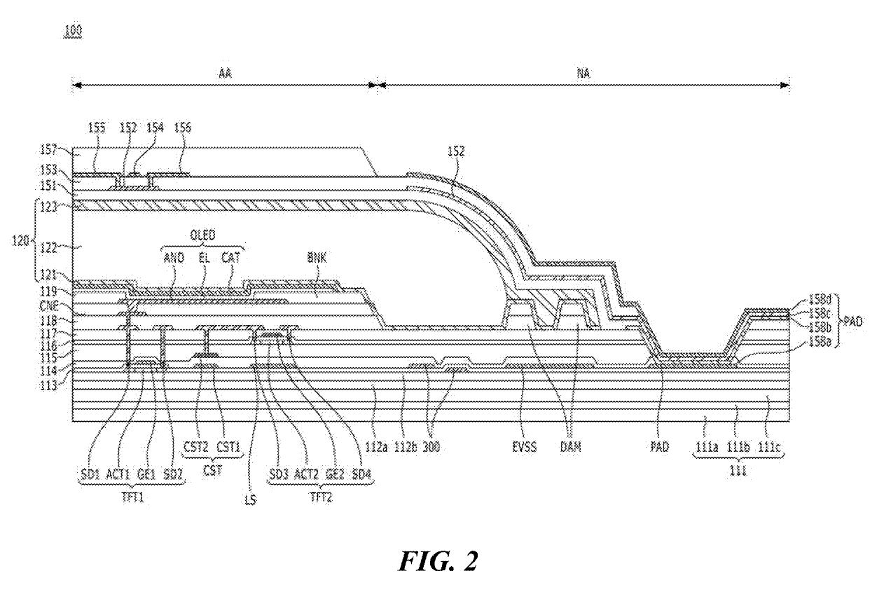

The data driver DIC may convert an image data signal into a data voltage and may output the data voltage through a data line. The data driver DIC may be configured as an integrated circuit (IC) and may be disposed at one side of the display panel 100. The data driver DIC may be configured as an IC type and may be implemented as a chip on film (COF) type mounted on a printed circuit board (PCB), or may be disposed as a chip on glass (COG) type mounted on the display panel 100, but embodiments of the present disclosure are not limited thereto. FIG. 2 is an exemplary diagram illustrating a stack structure of a display panel.

As illustrated in FIG. 2, transistors TFT1 and TFT2 and a capacitor CST for driving a light emitting device OLED disposed in the display area AA may be disposed on a substrate 111 of the display panel 100. The transistors TFT1 and TFT2 may include an oxide thin film transistor including an oxide semiconductor material and one thin film transistor of a driving transistor and a switching thin film transistor including a polycrystalline semiconductor material. In this case, the thin film transistor including the polycrystalline semiconductor material may be referred to as a polycrystalline thin film transistor TFT1, and the thin film transistor including the oxide semiconductor material may be referred to as an oxide thin film transistor TFT2. For example, the polycrystalline thin film transistor TFT1 may be a transistor connected to the light emitting device OLED, and the oxide thin film transistor TFT2 may be a transistor connected to the capacitor CST.

The substrate 111 may include a first substrate layer 111a, a second substrate layer 111b, and a third substrate layer 111c. The first substrate layer 111a and the third substrate layer 111c may be selected as an organic layer including polyimide, and the second substrate layer 111b disposed between the first substrate layer 111a and the third substrate layer 111c may be selected as an inorganic layer including oxide silicone (SiO₂). However, a structure of the substrate 111 may be merely one embodiment, and the substrate 111 may be used as a single layer including one substrate layer or a multilayer including two or more substrate layers.

A lower buffer layer 112a may be formed on the substrate 111. The lower buffer layer 112a may be for preventing the penetration of water from the outside and may be used by stacking an oxide silicone (SiO₂) layer as a multilayer. To protect elements from the penetration of water into the lower buffer layer 112a, an auxiliary buffer layer 112b may be further disposed.

The polycrystalline thin film transistor TFT1 may be formed on the substrate 111. The polycrystalline thin film transistor TFT1 may use a polycrystalline semiconductor material as an active layer. The polycrystalline thin film transistor TFT1 may include a first active layer ACT1 including a channel through which an electron or a hole moves, a first gate electrode GE1, a first source electrode SD1, and a first drain electrode SD2. A first gate insulation layer 113 may be disposed between the first gate electrode GE1 and the first active layer ACT1 and may be used by stacking an inorganic layer, such as an oxide silicone (SiO₂) layer or a nitride silicone (SiNx) layer, as a single layer or a multilayer.

The first active layer ACT1 may include a first channel region, a first source region disposed at one side with the first channel region between the one side and the other side, and a first drain region disposed at the other side. Each of the first source region and the first drain region may be a region which has conductivity by doping Group 5 or 3 impurity ions (for example, phosphorus (P) and boron (B)) on an intrinsic polycrystalline semiconductor material at a certain concentration.

The first channel region may allow the polycrystalline semiconductor material to maintain an intrinsic state and may provide a path through which an electron or a hole moves.

According to an embodiment, the polycrystalline thin film transistor TFT1 may be implemented in a top gate structure where the first gate electrode GE1 is disposed on the first active layer ACT1. Therefore, a first electrode CST1 included in the capacitor CST and a light blocking layer LS included in the oxide thin film transistor TFT2 may include the same material as that of the first gate electrode GE1. The first gate electrode GE1, the first electrode CST1, and the light blocking layer LS may be formed through one mask process, and thus, the number of mask processes may be reduced.

The first gate electrode GE1 may include a metal material. For example, the first gate electrode GE1 may be a single layer or a multilayer including one of molybdenum (Mo), aluminum (Al), chrome (Cr), gold (Au), titanium (Ti), nickel (Ni), neodymium (Nd), and copper (Cu), or an alloy thereof, but embodiments of the present disclosure are not limited thereto. A first interlayer insulation layer 114 may be disposed on the first gate electrode GE1. The first interlayer insulation layer 114 may be implemented with SiO₂ or SiNx.

The display panel 100 may further include an upper buffer layer 115, a second gate insulation layer 116, and a second interlayer insulation layer 117, which are sequentially disposed on the first interlayer insulation layer 114, and the polycrystalline thin film transistor TFT1 may include a first source electrode SD1 and a first drain electrode SD2, which are formed on the second interlayer insulation layer 117 and are respectively connected to the first source region and the first drain region.

The first source electrode SD1 and the first drain electrode SD2 may be a single layer or a multilayer including one of Mo, Al, Cr, Au, Ti, Ni, Nd, and Cu, or an alloy thereof, but embodiments of the present disclosure are not limited thereto.

The upper buffer layer 115 may separate the first active layer ACT1, implemented with a polycrystalline semiconductor material, from a second active layer ACT2 of the oxide thin film transistor TFT2 implemented with an oxide semiconductor material and may provide a basis for forming the second active layer ACT2.

The second gate insulation layer 116 may cover the second active layer ACT2 of the oxide thin film transistor TFT2. The second gate insulation layer 116 may be formed on the second active layer ACT2 implemented with an oxide semiconductor material, and thus, may be implemented as an inorganic layer. For example, the second gate insulation layer 116 may include SiO₂ or SiNx.

The second gate electrode GE2 may include a metal material. For example, the second gate electrode GE2 may be a single layer or a multilayer including one of Mo, Al, Cr, Au, Ti, Ni, Nd, and Cu, or an alloy thereof, but embodiments of the present disclosure are not limited thereto.

The oxide thin film transistor TFT2 may be formed on the upper buffer layer 115. The oxide thin film transistor TFT2 may include the second active layer ACT2 implemented with an oxide semiconductor material, a second gate electrode GE2 disposed on the second gate insulation layer 116, and a second source electrode SD3 and a second drain electrode SD4 disposed on the second interlayer insulation layer 117. The second active layer ACT2 may include an intrinsic second channel region, which is implemented with an oxide semiconductor material and is not doped with impurities, and a second source region and a second drain region which have conductivity by doping impurities thereon.

The oxide thin film transistor TFT2 may further include the light blocking layer LS which is disposed under the upper buffer layer 115 and overlaps the second active layer ACT2. The light blocking layer LS may prevent light from being irradiated onto the active layer 401 and may thus secure the reliability of the oxide thin film transistor TFT2. The light blocking layer LS may include the same material as that of the first gate electrode GE1 and may be formed on an upper surface of the first gate insulation layer 113. The light blocking layer LS may be electrically connected to the second gate electrode GE2 to configure a dual gate.

The second source electrode SD3 and the second drain electrode SD4 may be simultaneously formed of the same material on the second interlayer insulation layer 117 along with the first source electrode SD1 and the first drain electrode SD2, and thus, the number of mask processes may be reduced.

A second electrode CST2 may be disposed on the first interlayer insulation layer 114 to overlap the first electrode CST1, and thus, the capacitor CST may be implemented. The second electrode CST2, for example, may be a single layer or a multilayer including one of Mo, Al, Cr, Au, Ti, Ni, Nd, and Cu, or an alloy thereof.

The capacitor CST may store a data voltage applied through a data line DL for a certain time. The capacitor CST may include two electrodes corresponding to each other and a dielectric disposed therebetween. The first interlayer insulation layer 114 may be disposed between the first electrode CST1 and the second electrode CST2.

The first electrode CST1 or the second electrode CST2 of the capacitor CST may be electrically connected to the second source electrode SD3 or the second drain electrode SD4 of the oxide thin film transistor TFT2. However, embodiments of the present disclosure are not limited thereto, and a connection relationship of the capacitor CST may be changed based on a subpixel driving circuit.

A first planarization layer 118 and a second planarization layer 119 for planarizing a surface may be sequentially disposed on the subpixel driving circuit. Each of the first planarization layer 118 and the second planarization layer 119 may be an organic layer such as polyimide or acryl resin. The light emitting device OLED may be formed on the second planarization layer 119.

The light emitting device OLED may include an anode electrode layer (a first electrode layer) AND, a cathode electrode layer (a second electrode layer) CAT, and an emission layer EML disposed between the anode electrode layer AND and the cathode electrode layer CAT. In a case where a subpixel driving circuit is implemented to use in common a low-level voltage connected to the cathode electrode layer CAT, the anode electrode layer AND may be disposed as a separate electrode for each subpixel. On the other hand, in a case where a subpixel driving circuit is implemented to use in common a high-level voltage, the cathode electrode layer CAT may be disposed as a separate electrode for each subpixel.

The light emitting device OLED may be electrically connected to a driving element through a center electrode CNE disposed on the first planarization layer 118. For example, the anode electrode layer AND of the light emitting device OLED may be connected to, by the center electrode CNE, the first source electrode SD1 of the polycrystalline thin film transistor TFT1 configuring a subpixel driving circuit.

The anode electrode layer AND may be connected to the center electrode CNE exposed through a contact hole passing through the second planarization layer 119. The center electrode CNE may be connected to the first source electrode SD1 exposed through a contact hole passing through the first planarization layer 118.

The center electrode CNE may function as a medium which connects the first source electrode SD1 to the anode electrode layer AND. The center electrode CNE may include a conductive material such as Cu, Ag, Mo, or Ti.

The anode electrode layer AND may be formed in a multi-layer structure including a transparent conductive layer and an opaque conductive layer which is high in reflection efficiency. The transparent conductive layer may include a material, which is relatively large in work function value, such as indium tin oxide (ITO) or indium zinc oxide (IZO), and the opaque conductive layer may be formed in a single-layer or multi-layer structure including aluminum (Al), silver (Ag), copper (Cu), lead (Pb), molybdenum (Mo), titanium (Ti), or an alloy thereof. For example, the anode electrode layer AND may be formed in a structure where a transparent conductive layer, an opaque conductive layer, and a transparent conductive layer are sequentially stacked, or may be formed in a structure where a transparent conductive layer and an opaque conductive layer are sequentially stacked. The emission layer EML may be formed by stacking a hole-related layer, an organic emission layer, and an electron-related layer on the anode electrode layer AND in order or reverse order.

A bank layer BNK may be a subpixel definition layer which exposes the anode electrode layer AND of each subpixel. The bank layer BNK may be formed of an opaque material (for example, black) so as to prevent light interference between adjacent subpixels. In this case, the bank layer BNK may include a light blocking material including at least one of a color pigment, organic black, and carbon.

The cathode electrode layer CAT may be formed on an upper surface and a lateral surface of the emission layer EML so as to be opposite to the anode electrode layer AND with the emission layer EML therebetween. The cathode electrode layer CAT may be formed as one body to cover all of the display area AA. In a case where the cathode electrode layer CAT is applied to an organic light emitting display apparatus of a top emission type, the cathode electrode layer CAT may include a transparent conductive layer such as ITO or IZO.

An encapsulation layer 120 for preventing the penetration of water may be further disposed on the cathode electrode layer CAT. The encapsulation layer 120 may prevent the penetration of external water or oxygen into the emission layer EML vulnerable to external water or oxygen. To this end, the encapsulation layer 120 may include an at least one-layer inorganic encapsulation layer and an at least one-layer organic encapsulation layer, but is not limited thereto. The encapsulation layer 120 may include a first encapsulation layer 121, a second encapsulation layer 122, and a third encapsulation layer 123, which are sequentially stacked.

The first encapsulation layer 121 and the third encapsulation layer 123 may include an inorganic insulating material, which is capable of low temperature deposition, such as SiNx, SiOx, oxynitride silicon (SiON), or oxide aluminum (Al₂O₃). The first encapsulation layer 121 and the third encapsulation layer 123 may be deposited in a low temperature atmosphere, and thus, may prevent the damage of the emission layer EML vulnerable to a high temperature atmosphere when performing a deposition process of the first encapsulation layer 121 and the third encapsulation layer 123.

The second encapsulation layer 122 may perform a buffer function of decreasing a stress between layers caused by the bending of the display apparatus 10 and may planarize a step height between layers. The second encapsulation layer 122 may be formed on the substrate 111 where the first encapsulation layer 121 is formed and may include acryl resin, epoxy resin, phenolic resin, polyamide resin, polyimide resin, and polyethylene, or a non-photosensitive organic insulating material such as silicon oxycarbon (SiOC), or a photosensitive organic insulating material such as photo acryl, but embodiments of the present disclosure are not limited thereto.

In a case where the second encapsulation layer 122 is formed through an inkjet process, a dam DAM may be disposed to prevent the second encapsulation layer 122 from being diffused to an edge of the substrate 111. The dam DAM may be disposed closer to the edge of the substrate 111 than the second encapsulation layer 122. The dam DAM may prevent the second encapsulation layer 122 from being diffused to a pad region where a conductive pad disposed at an outermost portion of the substrate 111 is provided.

The dam DAM may be designed to prevent the diffusion of the second encapsulation layer 122, but in a case where the second encapsulation layer 122 is formed to flow over a height of the dam DAM when performing a process, the second encapsulation layer 122 which is an organic layer may be exposed at the outside, and due to this, water may easily penetrate into the light emitting device OLED. Accordingly, in order to solve such a problem, the dam DAM may be provided as ten or more to overlap each other.

The dam DAM may be disposed on the second interlayer insulation layer 117 of a non-display area NA. Also, the dam DAM may be formed simultaneously with the first planarization layer 118 and the second planarization layer 119. A lower layer of the dam DAM may be formed together when forming the first planarization layer 118, and an upper layer of the dam DAM may be formed together when forming the second planarization layer 119, and thus, the dam

DAM may be stacked and formed in a double structure. Accordingly, the dam DAM may include the same insulating material as that of the first planarization layer 118 and the second planarization layer 119, but embodiments of the present disclosure are not limited thereto.

The dam DAM may be formed to overlap a low-level voltage line EVSS. For example, the low-level voltage line EVSS may be disposed in a lower layer of a region, where the dam DAM is disposed, of the non-display area NA. The low-level voltage line EVSS may be disposed more outward than the gate driver 300 and may surround the display area AA. For example, the low-level voltage line EVSS may include the same material as that of the first gate electrode GE1, but is not limited thereto and may include the same material as that of the second electrode CST2 or the first source electrode SD1 and the first drain electrode SD2. The low-level voltage line EVSS may be electrically connected to the cathode electrode layer CAT so as to apply the low-level voltage EVSS to a plurality of subpixels included in the display area AA.

A touch layer may be disposed on the encapsulation layer 120. In the touch layer, a touch buffer layer 151 may be disposed between the cathode electrode layer CAT of the light emitting device OLED and a touch sensor metal layer including touch electrodes 155 and 156 and touch electrode connection lines 152 and 154.

The touch buffer layer 151 may prevent external water or a chemical solution (for example, a developer or an etchant), which is used in a manufacturing process of the touch sensor metal layer disposed on the touch buffer layer 151, from penetrating into the emission layer EML including an organic material. Accordingly, the touch buffer layer 151 may prevent the damage of the emission layer EML vulnerable to the chemical solution or water.

The touch buffer layer 151 may include an organic insulating material which has a low dielectric constant of 1 to 3 and is capable of being formed at a low temperature of a certain temperature (for example, 100 ℃) or less, so as to prevent the damage of the emission layer EML including an organic material vulnerable to a high temperature. For example, the touch buffer layer 151 may include an acrylic material, an epoxy-based material, or a siloxan-based material. The touch buffer layer 151 which includes an organic insulating material and has planarization performance may prevent the damage of the encapsulation layer 120 caused by the bending of an apparatus and the breakage of the touch sensor metal layer formed on the touch buffer layer 151.

According to a touch sensor structure based on a mutual capacitance, the touch electrodes 155 and 156 may be disposed on the touch buffer layer 151, and the touch electrodes 155 and 156 may be disposed to intersect with each other. The touch electrode connection lines 152 and 154 may electrically connect the touch electrodes 155 and 156 with each other. The touch electrode connection lines 152 and 154 and the touch electrodes 155 and 156 may be disposed in different layers with the touch insulation layer 153 therebetween. The touch electrode connection lines 152 and 154 may be disposed to overlap the bank layer BNK and may prevent a reduction in aperture ratio.

In the touch electrodes 155 and 156, a portion of the touch electrode connection line 152 may pass through an upper portion and a lateral surface of the encapsulation layer 120 and an upper portion and a lateral surface of the dam DAM and may be electrically connected to a touch driving circuit (not shown) through a touch pad PAD. A portion of the touch electrode connection line 152 may be supplied with a touch driving signal from a touch driving circuit and may transfer the touch driving signal to the touch electrodes 155 and 156, or may transfer touch sensing signals of the touch electrodes 155 and 156 to the touch driving circuit. The touch pad PAD may include a first layer 158a including the same material as that of the low-level voltage line EVSS, a second layer 158b including the same material as that of the anode electrode layer AND, a third layer 158c including the same material as that of the touch electrode connection line 152, and a fourth layer 158d including the same material as that of the touch electrodes 155 and 156.

A touch protection layer 157 may be disposed on the touch electrodes 155 and 156. In the drawings, the touch protection layer 157 is illustrated as being disposed on only the touch electrodes 155 and 156, but embodiments of the present disclosure are not limited thereto and the touch protection layer 157 may extend up to a previous portion or a next portion with respect to the dam DAM and may be disposed on the touch electrode connection line 152. A color filter (not shown) may be further disposed on the encapsulation layer 120, and the color filter may be disposed on the touch layer or may be disposed between the encapsulation layer 120 and the touch layer.

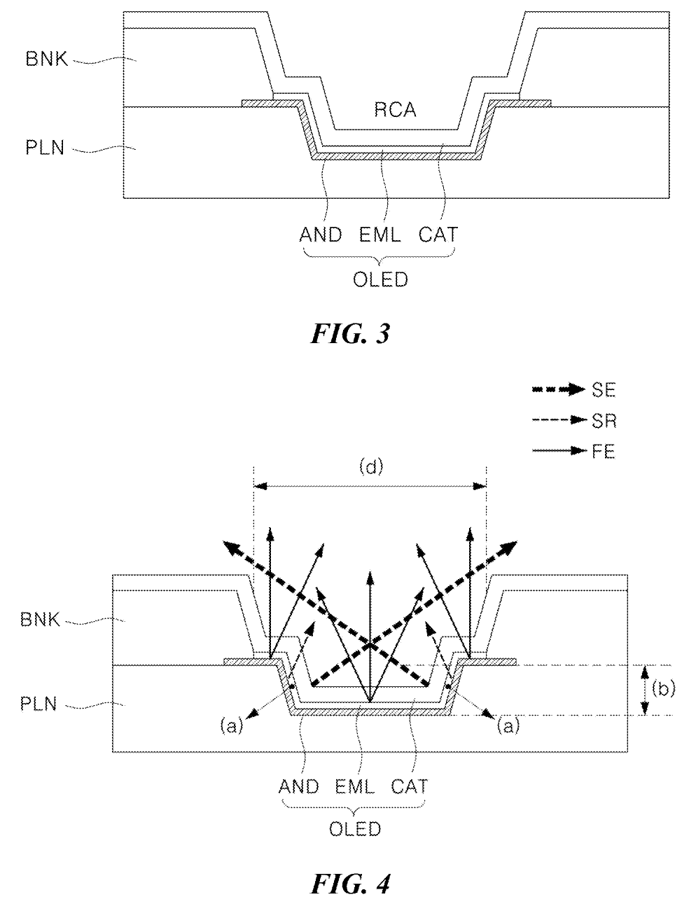

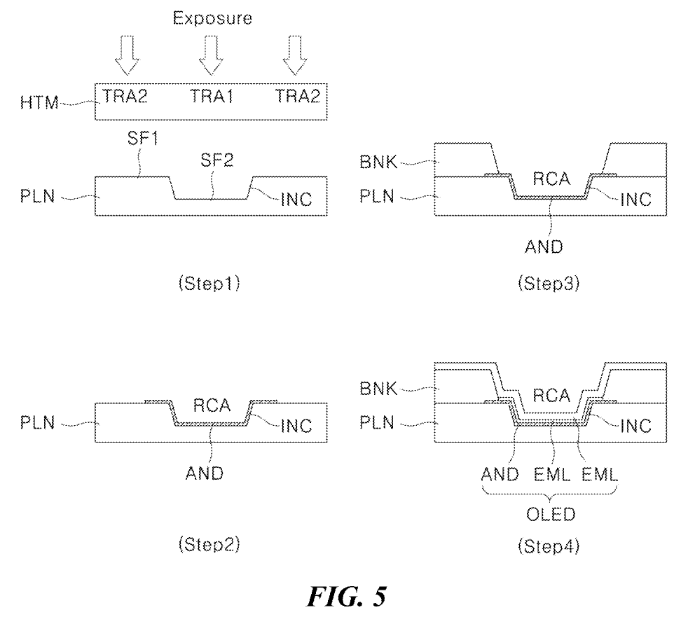

FIG. 3 is a cross-sectional view illustrating a light emitting device and a peripheral layer thereof according to a first embodiment, FIG. 4 is a diagram for describing a light extraction characteristic of a light emitting device according to the first embodiment, and FIG. 5 is a diagram for describing a method of manufacturing a light emitting device according to the first embodiment.

As illustrated in FIG. 3, a light emitting device OLED according to the first embodiment may include an anode electrode layer AND, an emission layer EML, and a cathode electrode layer CAT. The anode electrode layer AND may be disposed on a planarization layer PLN. An emission layer EML may be formed on the planarization layer PLN and may be disposed in a bank layer BNK including an opening portion. The cathode electrode layer CAT may be formed on an upper surface and a lateral surface of the bank BNK.

The planarization layer PLN may include a recessed region RCA configuring a stepped shape. The recessed region RCA may be a region where a surface corresponding to an opening portion of the bank layer BNK is removed to be recessed (or dented) in the planarization layer PLN.

The anode electrode layer AND, the emission layer EML, and the cathode electrode layer CAT configuring the light emitting device OLED may also have a recessed structure, based on the recessed region RCA of the planarization layer PLN disposed in a region corresponding to the opening portion of the bank layer BNK. Here, the planarization layer PLN may correspond to the second planarization layer 119 illustrated in FIG. 2. Accordingly, a structure formed under the planarization layer PLN may refer to FIG. 2, but is not limited thereto.

As illustrated in FIG. 4, in the light emitting device OLED according to the first embodiment, because the anode electrode layer AND, the emission layer EML, and the cathode electrode layer CAT configuring the light emitting device OLED have a recessed structure, based on the recessed region RCA of the planarization layer PLN, an emission area d may increase. Also, light emitted from the emission layer EML may be reflected through a lateral surface of the light emitting device OLED, and then, a light path may be changed to a forward direction, thereby increasing front luminance.

As described above, the light emitting device OLED according to the first embodiment may perform surface light emission FE, side light emission SE, and side reflection SR. The surface light emission FE may be defined as light emitted from a surface (or a front surface) of the emission layer EML configuring the light emitting device OLED, the side light emission SE may be defined as light emitted from a lateral surface of the emission layer EML, and the side reflection SR may be defined as light which is emitted from the lateral surface of the emission layer EML and is reflected through the anode electrode layer AND formed along a lateral surface of the recessed region RCA. The side light emission SE may be associated with a color shift characteristic and a luminance characteristic based on a viewing angle of the light emitting device OLED.

The light emitting device OLED according to the first embodiment may adjust two values which are greater than or equal to a side slope a of the light emitting device OLED defining a side taper of the recessed region RCA and a recessed depth b of the light emitting device OLED defining a depth of the recessed region RCA, and thus, may vary a color shift characteristic and a luminance characteristic. In the light emitting device OLED according to the first embodiment, a lifetime may be enhanced (long lifetime) based on an increase in emission area d, and power consumption may decrease based on the enhancement of a color shift characteristic and a luminance characteristic.

As illustrated in FIG. 5, a first step Step1 may be performed where a halftone mask HTM including a first transmissive region TRA1 and a second transmissive region TRA2 is aligned on the planarization layer PLN and is exposed to light, and then, is patterned. Therefore, a first surface SF1 of a first height and a second surface SF2 of a second height may be formed on the planarization layer PLN. Here, an equivalence relation between the first surface SF1 of the first height and the second surface SF2 of the second height may be “SF1 > SF2.” As the first step Step1 is performed, the recessed region RCA may be formed in the planarization layer PLN. Also, a side slope INC of the recessed region RCA may vary as described above with reference to FIG. 4.

Subsequently, a second step Step2 of forming the anode electrode layer AND on the planarization layer PLN may be performed. Accordingly, the anode electrode layer AND may be formed in the recessed region RCA including a flat surface and lateral surface of the planarization layer PLN.

Subsequently, a third step Step3 of forming the bank layer BNK on the planarization layer PLN and defining an opening portion may be performed. Accordingly, the bank layer BNK including the opening portion may be formed on the planarization layer PLN.

Subsequently, a fourth step Step4 of forming the emission layer EML in the opening portion of the bank layer BNK and forming the cathode electrode layer CAT may be performed. Accordingly, the anode electrode layer AND, the emission layer EML, and the cathode electrode layer CAT configuring the light emitting device OLED recessed by the recessed region RCA of the planarization layer PLN may be formed.

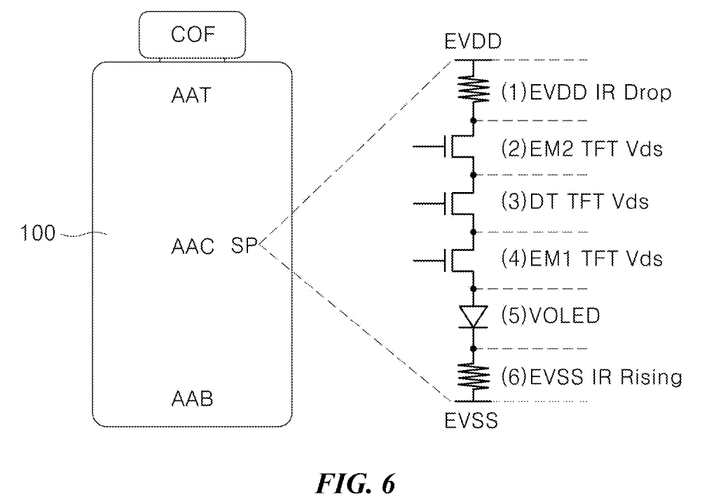

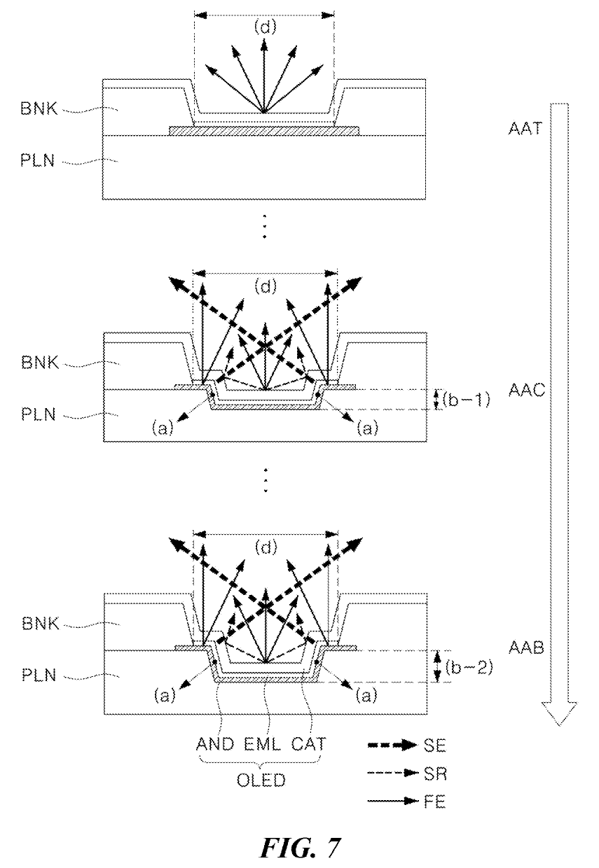

FIG. 6 is a plan view of a display panel according to a second embodiment, and FIG. 7 is a cross-sectional view of a light emitting device disposed in first to third regions of FIG. 6.

As illustrated in FIG. 6, a light emitting display apparatus may include a display panel 100 and a circuit which transfers an electrical signal or a voltage to the display panel 100, and for example, may include a circuit board COF with a data driver mounted thereon. The circuit board COF with the data driver mounted thereon and the display panel 100 may be connected to each other, based on a pad part formed in each thereof.

However, FIG. 6 merely illustrates one example according to the second embodiment, and as in FIG. 1, the data driver DIC may be mounted in a sub region SR of the display panel 100 and may be implemented as various types such as a structure (chip on panel) which is bent to a rear surface of the display panel 100, but embodiments of the present disclosure are not limited thereto. In FIG. 1, the data driver DIC may be mounted in the first pad region PA1, and the external circuit board FPCB may be attached to the second pad region PA2.

The display panel 100 may be divided into a first region AAT, a second region AAC, and a third region AAB from a region close to the circuit board COF. Here, the first region AAT may be defined as an upper region closest to the circuit board COF, the third region AAB may be defined as a lower region farthest away from the circuit board COF, and the second region AAC may be defined as a center region disposed between the first region AAT and the third region AAB.

The display panel 100 may include a subpixel SP. The subpixel SP may include a plurality of elements disposed between a high-level voltage line EVDD and a low-level voltage line EVSS. The plurality of elements included in the subpixel SP may be electrically affected between the high-level voltage line EVDD and the low-level voltage line EVSS, and an example thereof may correspond to (1) to (6) illustrated in FIG. 6.

In FIG. 6, (1) may be defined as the degree of drop of a high-level voltage (EVDD IR Drop) based on a current and a resistance. (2) may be defined as a drain-source voltage of a second emission control transistor (EM2 TFT Vds). (3) may be defined as a drain-source voltage of a driving transistor (DT TFT Vds). (4) may be defined as a drain-source voltage of a first emission control transistor (EM1 TFT Vds). (5) may be defined as a voltage of a light emitting device (VOLED). (6) may be defined as the degree of increase of a low-level voltage (EVSS IR Rising) based on a current and a resistance.

An electrical effect may vary based on a position at which the light emitting device OLED is disposed in the first region AAT, the second region AAC, and the third region AAB. Accordingly, the light emitting device according to the second embodiment may be disposed as follows, based on the above descriptions.

As illustrated in FIG. 7, a light emitting device OLED (a light emitting device including a non-recessed region) disposed in the first region AAT may be disposed on the planarization layer PLN which does not include a recessed region, and a light emitting device OLED disposed in the second region AAC and a light emitting device OLED (a light emitting device including a recessed region) disposed in the third region AAB may be disposed on the planarization layer PLN including a recessed region.

The light emitting device OLED disposed in the second region AAC and the light emitting device OLED disposed in the third region AAB may be disposed on the planarization layer PLN including a recessed region in common, but may differ in depth of a recessed region. For example, the planarization layer PLN of the second region AAC may have a first recessed depth (b-1), and the planarization layer PLN of the third region AAB may have a second recessed depth (b-2). Also, the first recessed depth (b-1) and the second recessed depth (b-2) may have a relationship “b-1 < b-2” therebetween. That is, the planarization layer PLN of the third region AAB may include a recessed region which is deeper than the planarization layer PLN of the second region AAC.

Furthermore, although not shown in FIG. 7, a recessed region of the planarization layer PLN may be formed toward the second region AAC from the first region AAT, and a depth of the recessed region may be deepened progressively (gradually) or by block units. To provide an additional description, the recessed region may be deepened by block units or progressively toward a second direction from a first direction.

Moreover, the recessed region of the planarization layer PLN may be deepened progressively or by block units toward the third region AAB from the second region AAC. In this case, a multi-tone mask may be used instead of the halftone mask described above with reference to FIG. 5.

In a case where the light emitting device OLED is implemented as a type according to the second embodiment, as the anode electrode layer AND and peripheral elements thereof are changed in shape, a lifetime may be enhanced (long lifetime), and a luminance characteristic and a viewing angle characteristic may be enhanced (front/viewing angle luminance increase), thereby decreasing power consumption.

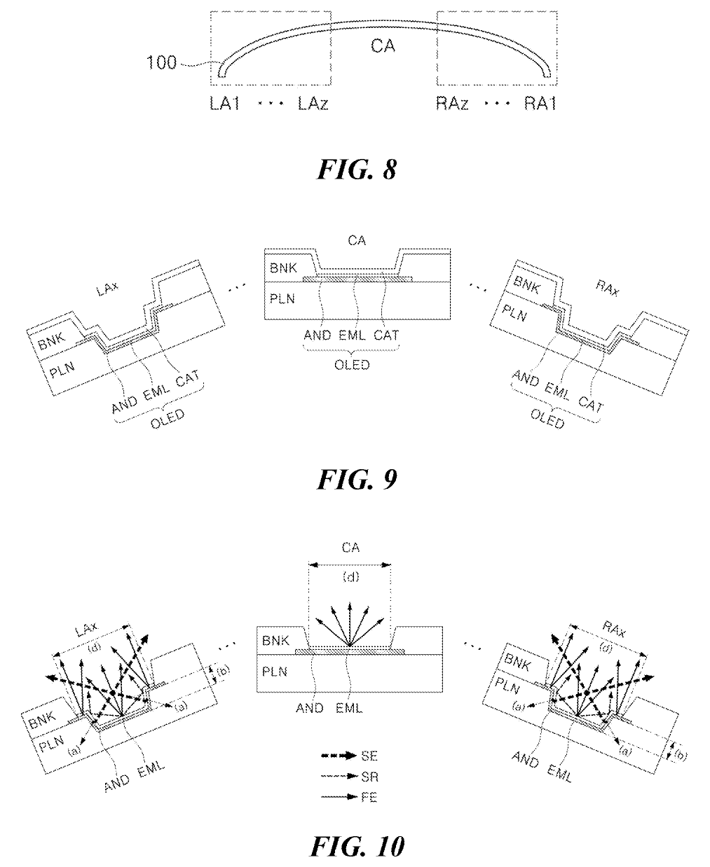

FIG. 8 is a side view of a display panel according to a third embodiment, FIG. 9 is a cross-sectional view of a light emitting device disposed in first to third regions of FIG. 8, FIG. 10 is a diagram for describing a light extraction characteristic of a light emitting device illustrated in FIG. 9, and FIG. 11 is a diagram illustrating a luminance compensation result of a display panel according to a third embodiment.

As illustrated in FIG. 8, according to the third embodiment, when a display panel 100 is seen from a lateral surface thereof, the display panel 100 may have a bending structure where a second region (LA1...LAz) and a third region (RA1...RAz) respectively defined at a left side and a right side with respect to a first region CA may be bent. Here, the first region CA may be defined as a center region of the display panel 100, the second region (LA1...LAz) may be defined as a left bending region of the display panel 100, and the third region (RA1...RAz) may be defined as a right bending region of the display panel 100. In the second region (LA1...LAz) and the third region (RA1...RAz), z may be an integer of 1 or more.

The display panel 100 having the bending structure may be recognized so that side luminance is relatively lower than front luminance, based on a mechanical or physical effect. The mechanical or physical effect may be changed based on a position at which the light emitting device OLED is disposed in the second region (LA1...LAz), the first region CA, and the third region (RA1...RAz). Accordingly, the light emitting device according to the third embodiment may be disposed as follows, based on the above descriptions. Hereinafter, an example where the second region (LA1...LAz) and the third region (RA1...RAz) of the display panel 100 is bent to have the same curved surface with respect to the first region CA will be described.

As illustrated in FIG. 9, a light emitting device OLED disposed in a first region CA may be disposed on a planarization layer PLN which does not include a recessed region, and a light emitting device OLED disposed in a second region LAx and a light emitting device OLED disposed in a third region RAx may be disposed on a planarization layer PLN including a recessed region. In the second region LAx and the third region RAx, x may be an arbitrary number which is less than z of the second region (LA1...LAz) and the third region (RA1...RAz) illustrated in FIG. 8.

The light emitting device OLED disposed in the second region LAx and the light emitting device OLED disposed in the third region RAx may have common features in that the light emitting devices OLED are disposed on the planarization layer PLN including the recessed region and are equal to each other in depth of the recessed region. That is, the light emitting device OLED disposed in the second region LAx and the light emitting device OLED disposed in the third region RAx may be disposed at the same points of a left side and a right side with respect to the first region CA.

Furthermore, although not shown in FIG. 9, a recessed region of the planarization layer PLN may be formed toward the second region LAx from the first region CA, and a depth of the recessed region may be deepened progressively or by block units. Also, a recessed region of the planarization layer PLN may be formed toward the third region RAx from the first region CA, and a depth of the recessed region may be deepened progressively or by block units. To provide an additional description, the recessed region may be deepened by block units or progressively toward a second direction from a first direction.

As illustrated in FIG. 11, in a display panel 100 according to a third embodiment Emb, a second region (LA1...LAz) and a third region (RA1...RAz) may have a light extraction characteristic which is the same as or similar to that of a first region CA. That is, in the display panel 100 according to the third embodiment Emb, a front visibility and a side visibility of an observer VIP may be similarly or identically compensated for, and thus, may improve a problem of luminance reduction LRA which occurs in a portion of each of a second region (LA1...LAz) and a third region (RA1...RAz) of a display panel 100 according to an experiment example Ref.

In a case where the light emitting device OLED is implemented as a type according to the third embodiment, as the anode electrode layer AND and peripheral elements thereof are changed in shape, a lifetime may be enhanced (long lifetime), and a luminance characteristic and a viewing angle characteristic may be enhanced (front/viewing angle luminance increase), thereby decreasing power consumption. Also, a phenomenon where a luminance of a bending surface is recognized to be relatively low may be improved by changing a structure (at least one of FIG. 10 (a), (b), and (c)) of a recessed region so that a level of region-based luminance is identically shown, instead of adding a structure of changing a light path or using a compensation method based on an algorithm (or minimization of algorithm-based compensation).

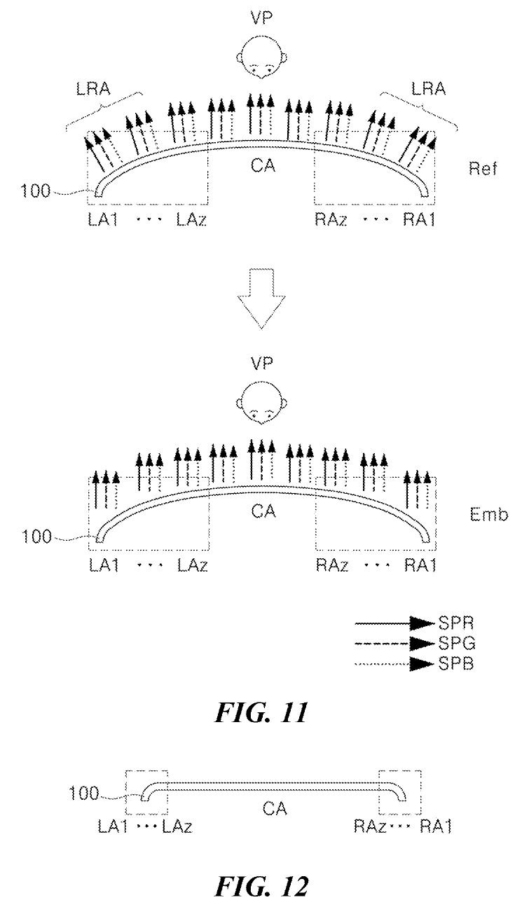

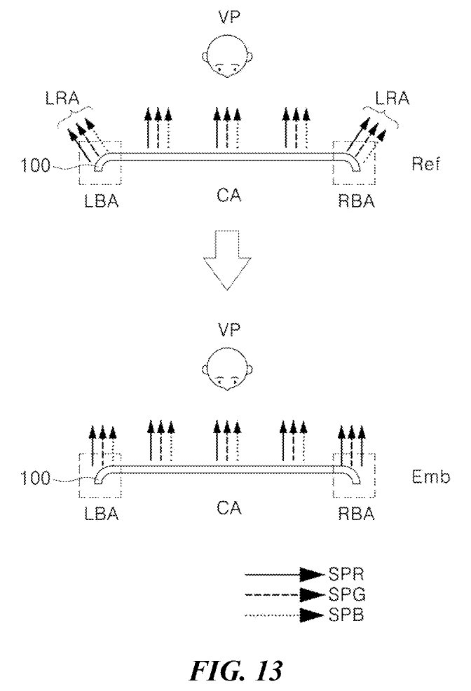

FIG. 12 is a side view of a display panel according to a fourth embodiment, and FIG. 13 is a diagram illustrating a luminance compensation result of a display panel according to a fourth embodiment.

As illustrated in FIG. 12, according to the fourth embodiment, when a display panel 100 is seen from a lateral surface thereof, the display panel 100 may have an edge curved structure where a second region (LA1...LAz) and a third region (RA1...RAz) respectively defined at a left side and a right side with respect to a first region CA may be bent. Here, the first region CA may be defined as a center region of the display panel 100, the second region (LA1...LAz) may be defined as a left edge curved region of the display panel 100, and the third region (RA1...RAz) may be defined as a right edge curved region of the display panel 100. In the second region (LA1...LAz) and the third region (RA1...RAz), z may be an integer of 1 or more.

The display panel 100 having the edge curved structure may be recognized so that side luminance is relatively lower than front luminance, based on a mechanical or physical effect. The mechanical or physical effect may be changed based on a position at which the light emitting device OLED is disposed in the first region CA, the second region (LA1...LAz), and the third region (RA1...RAz). Here, an arrangement structure of the light emitting device according to the fourth embodiment may be similar to the third embodiment described above, and thus, may refer to the third embodiment.

As illustrated in FIG. 13, in a display panel 100 according to a fourth embodiment Emb, a second region LBA which is a left edge curved region and a third region RBA which is a right edge curved region may have a light extraction characteristic which is similar to a first region CA. That is, in the display panel 100 according to the fourth embodiment Emb, a front visibility and a side visibility of an observer VIP may be similarly or identically compensated for, and thus, may improve a problem of luminance reduction LRA which occurs in a portion of each of a second region LBA and a third region RBA of a display panel 100 according to an experiment example Ref.

In a case where the light emitting device OLED is implemented as a type according to the fourth embodiment, as the anode electrode layer AND and peripheral elements thereof are changed in shape, a lifetime may be enhanced (long lifetime), and a luminance characteristic and a viewing angle characteristic may be enhanced (front/viewing angle luminance increase), thereby decreasing power consumption. Also, a phenomenon where a luminance of a curved surface is recognized to be relatively low may be improved by changing a structure of a recessed region so that a level of region-based luminance is identically shown, instead of adding a structure of changing a light path or using a compensation method based on an algorithm (or minimization of algorithm-based compensation).

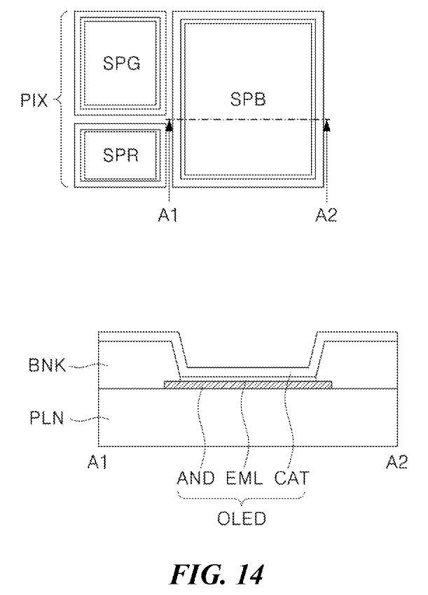

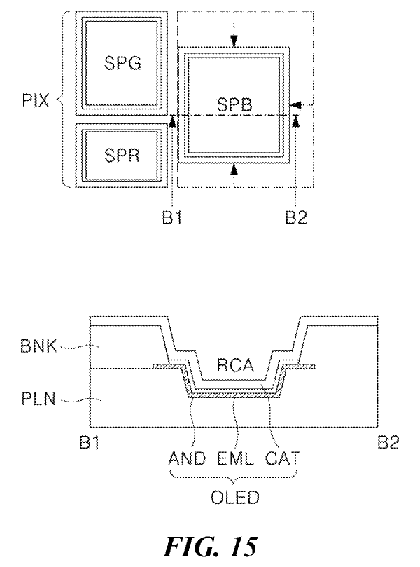

FIG. 14 is a diagram illustrating one of a cross-sectional view and a plan view of a pixel disposed in a first region of a display panel according to a fifth embodiment, and FIG. 15 is a diagram illustrating one of a cross-sectional view and a plan view of a pixel disposed in a second region or a third region of a display panel according to a fifth embodiment.

As illustrated in FIG. 14, a pixel PIX disposed in a first region of a display panel may include a red subpixel SPR, a green subpixel SPG, and a blue subpixel SPB. The first region may be defined as an upper region of the display panel close to a circuit board or a center region of the display panel.

Sizes of the subpixels included in the pixel PIX may increase in the order of the red subpixel SPR, the green subpixel SPG, and the blue subpixel SPB. An area of the blue subpixel SPB may be greater than or equal to a sum of an area of the red subpixel SPR and an area of the green subpixel SPG.

As seen in a region A1-A2 representing a cross-sectional surface of the blue subpixel SPB, the pixel PIX disposed in the first region of the display panel may include a light emitting device OLED formed on a planarization layer PLN which does not include a recessed region. For example, the pixel PIX disposed in the first region of the display panel may include the light emitting device OLED illustrated in AAT of FIG. 7, CA of FIG. 9, or CA of FIG. 13.

As illustrated in FIG. 15, a pixel PIX disposed in a second region or a third region of the display panel may include a red subpixel SPR, a green subpixel SPG, and a blue subpixel SPB. The second region or the third region may be defined as a center region or a lower region of the display panel relatively far away from the circuit board, or may be defined as a left region or a right region with respect to the center region of the display panel.

Sizes of the subpixels included in the pixel PIX may increase in the order of the red subpixel SPR, the green subpixel SPG, and the blue subpixel SPB, and an area of the blue subpixel SPB may be less than a sum of an area of the red subpixel SPR and an area of the green subpixel SPG. On the other hand, the red subpixel SPR and the green subpixel SPG may have similar sizes.

As seen in a region B1-B2 representing a cross-sectional surface of the blue subpixel SPB, the pixel PIX disposed in the second region or the third region of the display panel may include a light emitting device OLED formed on a planarization layer PLN including a recessed region RCA. For example, the pixel PIX disposed in the second region or the third region of the display panel may include the light emitting device OLED illustrated in AAC/AAB of FIG. 7, LAz/RAx of FIG. 9, or LAx/RAx of FIG. 13.

The red subpixel SPR may include a red light emitting device emitting red light, the green subpixel SPG may include a green light emitting device emitting green light, and the blue subpixel SPB may include a blue light emitting device emitting blue light.

The blue light emitting device emitting blue light among the light emitting devices included in the subpixels SPR, SPG, and SPB may be shorter in lifetime than the red and green light emitting devices. Accordingly, the blue light emitting device may be greater in subpixel size than the red and green light emitting devices, or may need a driving current which is higher than the red and green light emitting devices.

However, in a case where a pixel is configured by a combination of structures illustrated in FIGS. 14 and 15, or a pixel is configured in the structure illustrated in FIG. 15, a blue light emitting device may be driven based on a low driving current (a low current), and thus, a lifetime may be improved. Also, in a case where a pixel is configured by a combination of the structures illustrated in FIGS. 14 and 15, or a pixel is configured in the structure illustrated in FIG. 15, a size of the blue light emitting device may be reduced to be equal to a red light emitting device or a green light emitting device, and thus, the degree of freedom of design may be enhanced, and a resolution may increase.

Furthermore, in the fifth embodiment, an example may be described where the subpixels SPR, SPG, and SPB included in the pixel PIX have a tetragonal shape, and sizes thereof increase in the order of the red subpixel SPR, the green subpixel SPG, and the blue subpixel SPB, but embodiments of the present disclosure are not limited thereto. Also, in the fifth embodiment, an example where only the blue light emitting device is formed on the planarization layer PLN including the recessed region RCA is illustrated and described, but may be applied to at least one of the red light emitting device and the green light emitting device.

Therefore, a light emitting device including the recessed region RCA may be applied based on at least one of (1) a mechanical or physical strain characteristic of a display panel, (2) a light extraction characteristic of the subpixels SPR, SPG, and SPB included in the pixel PIX, and (3) an arrangement structure of the subpixels SPR, SPG, and SPB included in the pixel PIX. Also, the light emitting device including the recessed region RCA may vary in emission area, side slope, and recessed depth, based on at least one condition of (1) to (3).

Hereinabove, the present disclosure may improve light extraction efficiency and a viewing angle characteristic, based on a light emitting device including a recessed region and a non-recessed region or a light emitting device including a recessed region. Also, the present disclosure may secure a wide emission region in the same opening area and may enhance a front viewing angle and a side viewing angle, based on front light emission and side light emission. Also, the present disclosure may enhance (long lifetime) a lifetime, based on securing a wide emission region, and may enhance a luminance characteristic and a viewing angle characteristic (increase front/viewing angle luminance), thereby decreasing power consumption and minimizing a color shift.

The effects according to the present disclosure are not limited to the above examples, and other various effects may be included in the specification.

While the present disclosure has been particularly shown and described with reference to exemplary embodiments thereof, it will be understood by those of ordinary skill in the art that various changes in form and details may be made therein without departing from the spirit and scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a display panel including subpixels; and
a driver configured to drive the display panel,
wherein each of the subpixels comprises a first light emitting device disposed on a substrate and disposed on a planarization layer, the planarization layer including a recessed region, and
wherein the recessed region has a structure that varies based on a region defined on the substrate.

2. The display apparatus of claim 1, wherein the recessed region is formed by removing a portion of a surface of the planarization layer to define a recess, and
wherein a depth of the recessed region varies based on the region defined on the substrate.

3. The display apparatus of claim 1, wherein a side slope of the recessed region varies based on the region defined on the substrate.

4. The display apparatus of claim 1, wherein the recessed region is included in subpixels disposed in a second region and a third region with respect to a first region of the substrate.

5. The display apparatus of claim 4, wherein the subpixels disposed in the first region do not include the recessed region.

6. The display apparatus of claim 1, wherein the recessed region increases in depth either in discrete block units or in a continuous gradient along a second direction of the substrate from a first direction of the substrate.

7. The display apparatus of claim 1, wherein the display panel includes subpixels comprising a red subpixel, a green subpixel, and a blue subpixel, and
wherein the first light emitting device is included in at least one of the red subpixel, the green subpixel, and the blue subpixel.

8. The display apparatus of claim 7, wherein the first light emitting device is included in the blue subpixel.

9. A display apparatus comprising:
a substrate;
a planarization layer disposed on the substrate and including a recessed region where a surface of the planarization layer is recessed; and
a light emitting device disposed on the planarization layer,
wherein the recessed region has a shape that varies based on a region defined on the substrate.

10. The display apparatus of claim 9, wherein a depth of the recessed region varies based on the region defined on the substrate.

11. The display apparatus of claim 9, wherein a side slope of the recessed region varies based on the region defined on the substrate.

12. The display apparatus of claim 9, wherein the recessed region is included in pixels disposed in a second region and a third region with respect to a first region of the substrate.

13. The display apparatus of claim 12, wherein the pixels disposed in the first region do not include the recessed region.

14. The display apparatus of claim 9, wherein the recessed region is deepened by block units or progressively toward a second direction of the substrate from a first direction of the substrate.

15. The display apparatus of claim 9, wherein the recessed region is included in a pixel including a blue light emitting device emitting blue light.

16. The display apparatus of claim 1, wherein the structure of the recessed region is configured to compensate for luminance or color variation caused by bending or curvature of the substrate.

17. The display apparatus of claim 1, wherein the recessed region is formed only in planarization layers corresponding to blue subpixels.

18. A method of manufacturing a display apparatus, the method comprising:
forming a planarization layer on a substrate;
forming a recessed region by removing a surface of the planarization layer to be recessed; and
forming a first light emitting device on the planarization layer including the recessed region,
wherein the recessed region is patterned to have a structure that varies based on a region defined on the substrate.

19. The method of claim 18, wherein a depth of the recessed region varies based on the region defined on the substrate.
